(19) United States
(12) Patent Application Publication
(10) Pub. No.: US 2014/0005525 A1
(43) Pub. Date: Jan. 2, 2014

(54) Local Coil for Magnetic Resonance Imaging System

(71) Applicants: Yan Hong Chen, Shenzhen (CN); Zeng He He, Shenzhen (CN)

(72) Inventors: Yan Hong Chen, Shenzhen (CN); Zeng He He, Shenzhen (CN)

(21) Appl. No.: 13/928,208

(22) Filed: Jun. 26, 2013

(30) Foreign Application Priority Data
Jun. 27, 2012 (CN) 201210217659.3

(51) Int. Cl. G01R 33/34

(52) U.S. Cl. CPC G01R 33/34084
USPC 600/422

(57) ABSTRACT

A local coil includes a body portion. The body portion includes an inner conductor layer. The local coil further includes at least one elastic wing. The body portion and the at least one elastic wing form an accommodating space for accommodating a body part to be inspected.

This application claims the benefit of CN 201210217659.3, filed on Jun. 27, 2012, which is hereby incorporated by reference.

### TECHNICAL FIELD

The present embodiments relate to a local coil for a magnetic resonance imaging (MRI) system.

### BACKGROUND

MRI systems may operate with a number of various radio frequency (RF) antennas (e.g., coils). The RF antennas are used for transmitting and receiving RF pulses so as to excite atomic nuclei for the radiation of magnetic resonance signals and/or for the collection of induced magnetic resonance signals. Magnetic resonance systems may have large integrated coils (e.g., body coil) that are permanently fixed in the magnetic resonance scanners. The integrated coil may be arranged in a cylindrical manner around a collecting cavity for patients (e.g., using a structure referred to as a bird's nest or bird cage configuration), and in the collecting cavity for patients, during the measurement, the patient is supported on a bed (e.g., a patient positioning table).

In order to improve the signal to noise ratio (SNR) in the MRIs, the MRI scanners may use a local coil. The local coil is a receiving antenna that is placed close to the area to be imaged. For a number of body parts, dedicated local coils (e.g., shoulder coil, wrist coil, head coil, spine coil, entry coil for prostate imaging, and the like) are provided. For a shoulder imaging, a dedicated local coil for the shoulder is provided by the current MRI systems. The local coils may be easily placed on the body of patient for economic reasons (e.g., cost, scanning time, workflow). The local coils may make the patient feel comfortable. A local coil may include a machined casing that accommodates a plurality of antennas (e.g., annular or butterfly antennas) and a plurality of active electronics. The active electronics may include a low noise amplifier and a tuning/detuning circuit for an antenna.

Considering the aspects of the structure and the shape, a local coil may make the inner cavity of the coil conform as much as possible to the shape of the part to be inspected, so as to achieve a higher filling rate, and to improve the SNR, thereby obtaining a high image quality.

According to prior art, the current shoulder arrays are, for example, of a shell shape as shown in FIG. 1. To enable the local coils to be placed as close as possible to the volumes to be imaged, local coils of different sizes have been constructed so as to take various skeletons (shoulder sizes) of the patient population into account.

The local coil may conform to the ergonomics principles so as to improve the subjects' feelings of comfort and durability.

The local coil may be able to be easily and flexibly fitted in place and removed.

The materials used may have no impact on the image quality.

Shown in FIG. 1 is a shoulder coil according to prior art. The shoulder coil of the prior art includes a base plate 101 for fixing the shoulder coil onto a bed, a coil 102, a connecting wire 103 and a connecting port 104, as shown in FIG. 1. Shown in FIGS. 2A and 2B is the positioning workflow of the shoulder coil according to prior art. As shown in FIG. 2A. The shoulder coil is fixed onto the bed by the base plate 101. Then, the subject to be inspected lies flat on the bed and adjusts the position of his or her own body to move toward the shoulder coil. As shown in FIG. 2B, the subject to be inspected places his or her shoulder into the shoulder coil.

### SUMMARY AND DESCRIPTION

As shown in FIG. 1, the casing of the shoulder coil in the prior art may be of a rigid plastic structure that is manufactured by a molding process such as injection molding or resin casting and the like. The inner conductor layer of the shoulder coil is arranged inside the rigid plastic structure. The advantages of a rigid coil are accuracy in shape and reliability in use, but the structure of such a shoulder coil lacks adaptability, as the shape is unchangeable. In order to adapt to various subjects to be inspected, a magnetic resonance system may be provided with different types of shoulder coils. Thus, as the operator selects according to the somatotype of the subject to be inspected from among these different types of shoulder coils and conducts a change if not suited, the workflow is complicated. It is difficult to be easily and flexibly fitted in place and removed in a few special cases.

Aiming at the above-mentioned adaptability issue, a shoulder coil is proposed in Chinese patent application numbered CN101874731A. The casing of the shoulder coil is divided into an upper part (e.g. rear portion) and a lower part (e.g., front portion), so as to adapt to different subjects to be inspected. Because rigid materials are used, however, the shoulder coil according to the Chinese patent application CN101874731A may be improved in terms of the feeling of comfort and tolerance of the subjects to be inspected. Additionally, the workflow may be improved in terms of adjustment.

The scope of the present invention is defined solely by the appended claims and is not affected to any degree by the statements within this summary.

The present embodiments may obviate one or more of the drawbacks or limitations in the related art. For example, the adaptability of a local coil may be improved, a workflow may be simplified, and the local coil may be made flexible for a subject to be inspected to fit in place and remove.

One embodiment of a local coil includes a body portion, and the body portion includes an inner conductor layer. The shoulder coil also includes at least one elastic wing. The body portion and the at least one elastic wing form an accommodating space for accommodating a part to be inspected.

In one embodiment, the local coil includes two of the elastic wings, which are mounted respectively at two sides of the body portion.

In one embodiment, the local coil further includes two tightening belts that are fixed respectively on the two elastic wings. The two tightening belts are fixed on the two elastic wings with connectors matching with each another.

In one embodiment, the local coil includes one elastic wing and a base plate. The one elastic wing and the base plate are mounted respectively at two sides of the body. The base plate may be fixed to a bed.

In one embodiment, the elastic wing is inclined toward the inside of said accommodating space, so that the opening of the accommodating space is narrower than the inner diameter of the accommodating space.

In one embodiment, the angle between the elastic wing and the body portion is adjustable.

In another embodiment, the elastic wing includes an inner conductor layer, and the inner conductor layer of the elastic wing is electrically connected to the inner conductor layer of the body portion.

In one embodiment, a casing of the body portion is of a rigid plastic that is manufactured by a molding process such as injection molding, snap-back thermoforming or resin casting. Alternatively or additionally, a casing of the elastic wing is of an elastic polymer material that is manufactured by injection molding, casting or hot-pressing process.

In one embodiment, the elastic polymer material is an elastic plastic or foamed plastic.

In another embodiment, a magnetic resonance imaging system, in which any one of above-mentioned local coils is used, is provided.

### BRIEF DESCRIPTION OF THE DRAWINGS

FIG. 1 shows a shoulder coil according to prior art;

FIGS. 2A and 2B show a positioning workflow of the shoulder coil according to prior art;

FIG. 3A is a schematic view of one embodiment of a shoulder coil;

FIG. 3B is a sectional view of the shoulder coil of FIG. 3A; and

FIGS. 4A and 4B show one embodiment of a positioning workflow of the shoulder coil of FIGS. 3A and 3B.

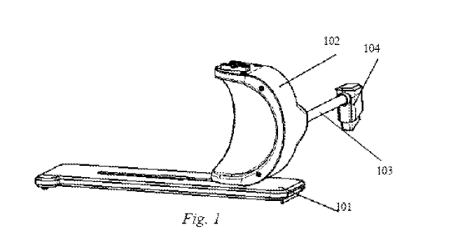

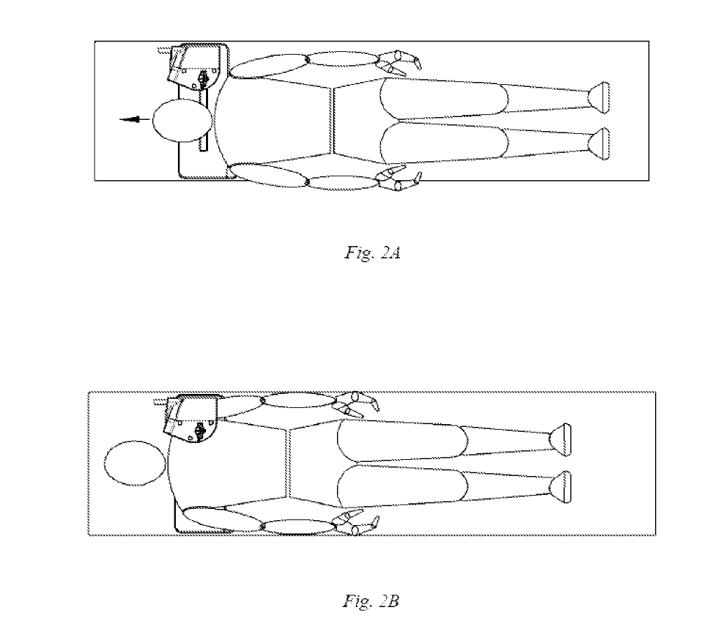

### DETAILED DESCRIPTION

A coil includes a rigid component and an elastic component. The size and shape of the coil is adjusted by adjusting the elastic component so as to adapt to different somatotypes of various subjects to be inspected. In the following, the present embodiments are illustrated with two embodiments of a shoulder coil.

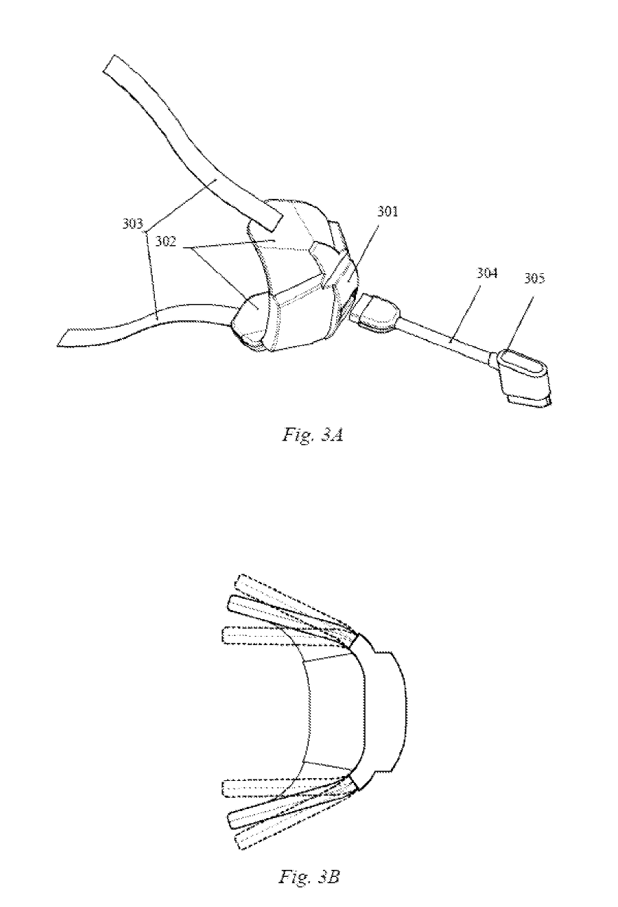

FIG. 3A is a schematic view of a shoulder coil according to a first embodiment, and FIG. 3B is a sectional view of the shoulder coil according to the first embodiment. As shown in FIG. 3, the shoulder coil includes a body portion 301, two elastic wings 302, two tightening belts 303, a connecting wire 304 and a connecting port 305. The body portion 301 is located between the two elastic wings 302 (e.g., each of two sides of the body portion 301 is connected with a respective elastic wing 302). The tightening belts 303 are respectively connected to an elastic wing 302 and have connectors matching with each other. The connecting wire 304 is electrically connected between the body portion 301 and the connecting port 305 so as to conduct signals between the two. The connecting port 305 is connected to the connecting wire 304 for sending signals to a magnetic resonance system.

A casing of the body portion 301 is a rigid plastic that is manufactured by a molding process such as injection molding, snap-back thermoforming or resin casting and like. The body portion 301 presents a semi-spherically shaped curved surface, forming a space for accommodating the shoulder of a subject to be inspected. Inside of the space for accommodating the shoulder, an inner conductor layer (e.g., copper sheet and insulating layer) for constituting a coil circuit is mounted.

The casings of the elastic wings 302 are made of an elastic polymer material (e.g., an artificial elastic plastic or a foamed plastic) and are manufactured by a molding process such as injection molding, casting or hot pressing and the like. Alternatively, the casings of the elastic wings 302 may be made of synthesized leather or natural leather. The elastic wings 302 present a fan-shaped curved surface or fan-shaped plane, forming a space for accommodating the shoulder of a subject to be inspected. An inner conductor layer (e.g., copper sheet and insulating layer) for constituting a coil circuit may be mounted inside of the elastic wings 302.

The elastic wings 302 include the following two status and operation modes.

First, both elastic wings 302 are inclined toward the inside of the space formed by the body portion 301 and the elastic wings 302 (e.g., both elastic wings 302 are inclined toward each other causing the opening of the accommodating space to be narrower than the inner diameter of said accommodating space, so as to form an opening narrower than the shoulder of the subject to be inspected). Thus, when the shoulder of the subject to be inspected is placed into the space formed by the body portion 301 and the elastic wings 302, the elastic deformation generated in both elastic wings 302 causes that the opening becomes larger and generates a clamping force on the shoulder of the subject to be inspected, thereby fastening the shoulder coil to the shoulder of the subject to be inspected. When the shoulder of the subject to be inspected is removed from the space formed by the body portion 301 and the elastic wings 302, both elastic wings 302 recover to the original state.

Second, the two elastic wings 302 are parallel with each other, while the angle between the two elastic wings 302 and the body portion 301 is adjustable. Accordingly, based on the size and shape of the shoulder of the subject to be inspected, by adjusting the positions of the elastic wings 302 (e.g., adjusting the angle between the elastic wings 302 and the body portion 301), the shoulder coil is enabled to adapt to the shoulder of the subject to be inspected and to generate a pressing force on the shoulder of the subject to be inspected, so as to fasten the shoulder of the subject to be inspected into the space formed by the body portion 301 and the elastic wings 302. As shown in FIG. 3B, position I is the regular position of the elastic wings 302, position II is an enlarged position for the elastic wings 302 to adapt to a larger shoulder volume of a subject to be inspected, and position III is a narrowed position for the elastic wings 302 to adapt to a smaller shoulder volume of a subject to be inspected.

The external connection between the body portion 301 and the elastic wings 302 may be implemented in a manner of latching, embedding, screw connecting, bonding and the like, and the internal connection between the body portion 301 and the elastic wings 302 may be implemented in a manner of welding, riveting, spring snapping or screw connecting and the like so as to achieve electrical conduction.

The tightening belts 303 are respectively connected to the elastic wings 302 and have connectors matching with each other for fastening the shoulder coil onto the shoulder of the subject to be inspected, so as to avoid displacement.

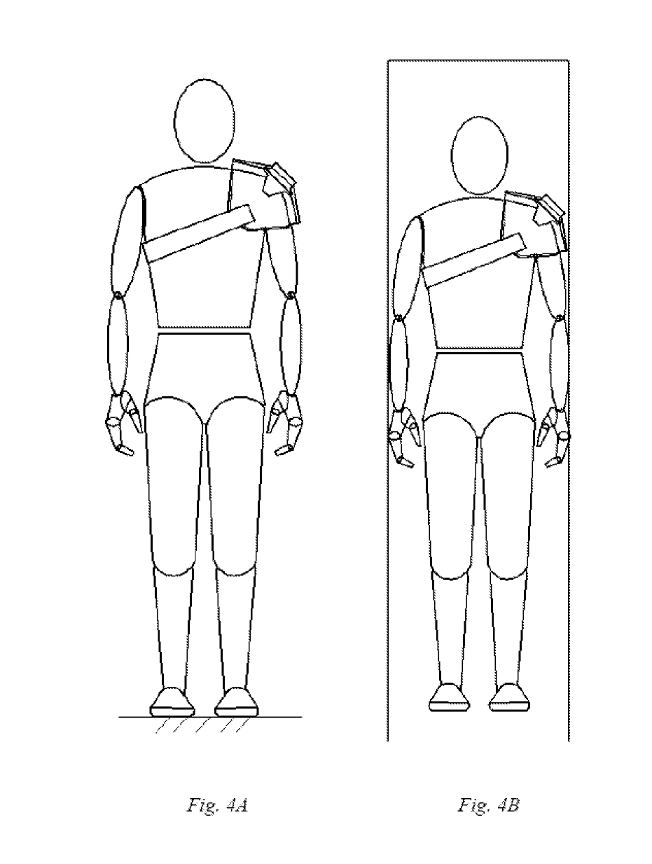

FIGS. 4A and 4B are a positioning workflow of the shoulder coil when the shoulder coil according to one embodiment is in use, as shown in FIG. 4A, at the standing pose of a subject to be inspected. The shoulder coil is fastened onto the shoulder of the subject to be inspected. As shown in FIG. 4B, the subject to be inspected having the shoulder coil fastened on the shoulder then lies down flat on the bed.

For the shoulder coil, due to the providing of the elastic wings causing that only one shoulder coil is used by the magnetic resonance system for various shoulder forms of different subjects to be inspected, the provision of a number of shoulder coils in different sizes is not required. Also, the tedious workflow for trying on different shoulder coils is avoided. The feeling of comfort and the tolerance of the subject to be inspected for the usage thereof are also improved. A simple and flexible process for the fitting in place and removing of the shoulder coil is also provided. Due to the provision of a rigid body portion, the inner conductor layer is accurate in shape, reliable in use, and less affected by the motions of a shoulder. According to different requirements, one or more of the present embodiments may also be used for other parts such as neck, wrist, arm, leg, waist and abdomen.

A shoulder coil according to a second embodiment includes a base plate for fixing the shoulder coil onto a bed, a body portion, an elastic wing, a connecting wire and a connecting port. The body portion 301 is located between the base plate and the elastic wing (e.g., one side of the body portion (lower side) is connected to the base plate, while the other side (upper side) is connected to the elastic wing). The connecting wire is electrically connected between the body portion and the connecting port, so as to conduct signals between the two. The connecting port is connected to the connecting wire for sending signals to a magnetic resonance system.

The casing of the body portion is a rigid plastic that is manufactured by molding processes such as injection molding, snap-back thermoforming or resin casting. The body portion presents a semi-spherical curved surface, forming a space for accommodating the shoulder of a subject to be inspected. An inner conductor layer (e.g., copper sheet and insulating layer) for constituting a coil circuit is mounted inside of the space for accommodating the shoulder.

The casing of the elastic wing is made of an elastic polymer material, such as an artificial elastic plastic or a foamed plastic, and is manufactured by a molding process such as injection molding, casting or hot pressing. Alternatively, the casing of the elastic wing may me made of synthesized leather or natural leather. The elastic wing has a fan-shaped curved surface or a fan-shaped plane that converges inwardly toward the shoulder of the subject to be inspected, forming a space for accommodating the shoulder of the subject to be inspected and generating an elastic force against the shoulder of the subject to be inspected, so as to fasten the shoulder of the subject to be inspected into the space formed by the body portion and the elastic wing. An inner conductor layer (e.g., copper sheet and insulating layer) for constituting a coil circuit may be mounted inside of the elastic wing.

The elastic wing includes the following two status and operation modes.

First, the elastic wing is inclined toward the inside of the space formed by the body portion and the elastic wing (e.g., the elastic wing is inclined toward the bed plane (base plate plane) causing that the opening of the accommodating space is narrower than the inner diameter of the accommodating space) so as to form an opening narrower than the shoulder of the subject to be inspected. Thus, when the shoulder of the subject to be inspected is placed into the space formed by the body portion and the elastic wings, the elastic deformation generated in the elastic wing causes that the opening becomes larger and generates a clamping force on the shoulder of the subject to be inspected, thereby fastening the shoulder coil to the shoulder of the subject to be inspected. When the shoulder of the subject to be inspected is removed from the space formed by the body portion and the elastic wings, the elastic wing recovers to the original state.

Second, the elastic wing is parallel with respect to the bed plane (e.g., base plate plane), but the angle between the elastic wing and the body portion is adjustable. Based on the size and shape of the shoulder of the subject to be inspected, by adjusting the position of the elastic wing (e.g., adjusting the angle between the elastic wing and the body portion), the shoulder coil is enabled to adapt to the shoulder of the subject to be inspected and to generate a pressing force on the shoulder of the subject to be inspected, so as to fasten the shoulder of the subject to be inspected into the space formed by the body portion and the elastic wing.

The external connection between the body portion and the elastic wing may be implemented in a manner of latching, embedding, screw connecting, bonding and the like, and the internal connection between the body portion and the elastic wings may be implemented in a manner of welding, riveting, spring snapping or screw connecting and the like so as to achieve electrical conduction.

For the shoulder coil, due to the providing of the elastic wing causing that only one shoulder coil is needed by the magnetic resonance system for various shoulder forms of different subjects to be inspected, the provision of a number of shoulder coils in different sizes is not required. Additionally, the tedious workflow for the trying on of different shoulder coils is avoided. The feeling of comfort and the tolerance of the subject to be inspected for the usage thereof are also improved. A simple and flexible process for the fitting in place and removing of the shoulder coil is also provided. Due to the provision of a rigid body portion, the inner conductor layer of the magnetic resonance system is accurate in shape, reliable in use, and less affected by the motions of the coil. According to different requirements, one or more of the present embodiments may also be used for other parts such as neck, wrist, arm, leg, waist and abdomen.

The local coil (e.g., a shoulder coil) includes a body portion. The body portion includes an inner conductor layer. The shoulder coil further includes at least one elastic wing. The body portion and the at least one elastic wing form an accommodating space for accommodating a body part to be inspected. A magnetic resonance system may use only one shoulder coil for various shoulder forms of different subjects to be inspected, while the tedious workflow for the trying on of different shoulder coils is avoided. The feeling of comfort and the tolerance of the subject to be inspected during the usage are also improved. A simple and flexible process for the fitting-in and removing of the shoulder coil is provided. Due to the provision of a rigid body portion, the inner conductor layer is accurate in shape, reliable in use, and less affected by the motions of a shoulder.

It is to be understood that the elements and features recited in the appended claims may be combined in different ways to produce new claims that likewise fall within the scope of the present invention. Thus, whereas the dependent claims appended below depend from only a single independent or dependent claim, it is to be understood that these dependent claims can, alternatively, be made to depend in the alternative from any preceding or following claim, whether independent or dependent, and that such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A local coil comprising:
a body portion comprising an inner conductive layer; and
at least one elastic wing,
wherein the body portion and the at least one elastic wing form an accommodating space for accommodating a part to be inspected.

2. The local coil as claimed in claim 1, wherein the at least one elastic wing comprises two elastic wings that are mounted respectively at two sides of the body portion.

3. The local coil as claimed in claim 2, further comprising two tightening belts that are fixed respectively on the two elastic wings,
wherein the two tightening belts are fixed on the two elastic wings with connectors matching with each another.

4. The local coil as claimed in claim 1, further comprising a base plate,
wherein the at least one elastic wings comprises elastic wings mounted respectively at two sides of said body, in which said base plate can be fixed to a bed.

5. The local coil as claimed in claim 2, wherein an elastic wing of the at least two elastic wings is inclined toward an inside of the accommodating space, so that an opening of the accommodating space is narrower than an inner diameter of the accommodating space.

6. The local coil as claimed in claim 2, wherein an angle between an elastic wing of the two elastic wings and the body portion is adjustable.

7. The local coil as claimed in claim 2, wherein an elastic wing of the two elastic wings comprises an inner conductive layer, the inner conductive layer of the elastic wing being electrically connected to the inner conductive layer of the body portion.

8. The local coil as claimed in claim 1, wherein a casing of the body portion is of a rigid plastic,
wherein the casing is manufactured by a molding process, snap-back thermoforming or resin casting, a casing of the at least one elastic wing is of an elastic polymer material that is manufactured by injection molding, casting or hot-pressing process, or a combination thereof.

9. The local coil as claimed in claim 8, wherein the molding process is injection molding.

10. The local coil as claimed in claim 8, wherein the elastic polymer material is an elastic plastic or foamed plastic.

11. A magnetic resonance imaging system comprising:
a local coil comprising:
a body portion comprising an inner conductive layer; and
at least one elastic wing,
wherein the body portion and the at least one elastic wing form an accommodating space for accommodating a part to be inspected.

12. The magnetic resonance imaging system as claimed in claim 11, wherein the at least one elastic wing comprises two elastic wings that are mounted respectively at two sides of the body portion.

13. The magnetic resonance imaging system as claimed in claim 12, further comprising two tightening belts that are fixed respectively on the two elastic wings, wherein the two tightening belts are fixed on the two elastic wings with connectors matching with each another.

14. The magnetic resonance imaging system as claimed in claim 11, further comprising a base plate,
wherein the at least one elastic wings comprises elastic wings mounted respectively at two sides of said body, in which said base plate can be fixed to a bed.

15. The magnetic resonance imaging system as claimed in claim 12, wherein an elastic wing of the at least two elastic wings is inclined toward an inside of the accommodating space, so that an opening of the accommodating space is narrower than an inner diameter of the accommodating space.

16. The magnetic resonance imaging system as claimed in claim 12, wherein an angle between an elastic wing of the two elastic wings and the body portion is adjustable.

17. The magnetic resonance imaging system as claimed in claim 12, wherein an elastic wing of the two elastic wings comprises an inner conductive layer, the inner conductive layer of the elastic wing being electrically connected to the inner conductive layer of the body portion.

18. The magnetic resonance imaging system as claimed in claim 11, wherein a casing of the body portion is of a rigid plastic,
wherein the casing is manufactured by a molding process, snap-back thermoforming or resin casting, a casing of the at least one elastic wing is of an elastic polymer material that is manufactured by injection molding, casting or hot-pressing process, or a combination thereof.

19. The magnetic resonance imaging system as claimed in claim 18, wherein the molding process is injection molding.

20. The magnetic resonance imaging system as claimed in claim 18, wherein the elastic polymer material is an elastic plastic or foamed plastic.
